(19) United States
(12) Patent Application Publication
(10) Pub. No.: US 2014/0266448 A1
(43) Pub. Date: Sep. 18, 2014

(54) ADAPATIVE POWER AMPLIFIER

(71) Applicant: QUALCOMM INCORPORATED, San Diego, CA (US)

(72) Inventors: Jeongwon Cha, San Diego, CA (US); Chang-Ho Lee, San Diego, CA (US); Woonyun Kim, San Diego, CA (US); Aristotele Hadjichristos, San Diego, CA (US); Yu Zhao, San Diego, CA (US)

(73) Assignee: QUALCOMM Incorporated, San Diego, CA (US)

(21) Appl. No.: 13/828,646

(22) Filed: Mar. 14, 2013

(51) Int. Cl. H03F 3/193; H03F 3/21

(52) U.S. Cl. CPC H03F 3/193; H03F 3/21
USPC 330/261

(57) ABSTRACT

Exemplary embodiments are related to an envelope-tracking power amplifier. A device may include a first transistor of a plurality of transistors in a stacked configuration configured to receive a supply voltage varying with an envelope of a radio-frequency (RF) input signal. The device may further include a second transistor of the plurality in the stacked configuration coupled to a reference voltage and configured to receive a dynamic bias voltage varying inversely proportional to the supply voltage.

### BACKGROUND

1. Field

The present invention relates generally to power amplifiers. More specifically, the present invention relates to embodiments for reducing gain variation of an envelope-tracking power amplifier.

2. Background

Power amplifiers are widely used in various wireless communication systems to provide amplification and output drive for radio-frequency RF signals prior to transmission over the air. For example, power amplifiers are used in Global System for Mobile Communications (GSM) systems, Wideband Code Division Multiple Access (WCDMA) systems, etc. Power amplifiers are also used in base stations as well as in terminals.

Power amplifiers are typically required to meet various system specifications for spectral mask, transmit time mask, harmonics distortion, output noise, output power level, etc. GSM and WCDMA systems also require a terminal to be able to adjust its output power over a wide range (e.g., 30 dB or more for GSM, and more than 70 dB for WCDMA).

Envelope-tracking power amplifiers, which are known in the art, are configured to receive a RF signal and a power supply voltage that varies according to an envelope of the RF signal. However, a gain of an envelope-tracking power amplifier may drop substantially as the supply voltage decreases, and, therefore, cause amplitude-to-amplitude (AM-AM) distortion, which may lead to degraded linearity performance of the envelope-tracking power amplifier. Further, the gain variation (i.e., the gain droop over a supply voltage) may increase due to a multi-stack power device, which may be used to enhance reliability. In addition, due to the gain variation of the envelope-tracking power amplifier, the supply voltage range is limited, and the efficiency improvement is diminished.

A need exists for an enhanced power amplifier. More specifically, a need exists for embodiments related to reducing gain variation of an envelope-tracking power amplifier.

### BRIEF DESCRIPTION OF THE DRAWINGS

FIG. 1 illustrates a device including an envelope-tracking power amplifier.

FIG. 2 is a plot depicting signals associated with a power amplifier and an envelope-tracking power amplifier.

FIG. 3 is a plot depicting various signals associated with an envelope-tracking power amplifier.

FIG. 4A illustrates a device including a plurality of switches in a stacked configuration, according to an exemplary embodiment of the present invention.

FIG. 4B is another illustration of the device depicted in FIG. 4A.

FIG. 5 is a plot illustrating various voltages associated with the device depicted in FIGS. 4A and 4B.

FIG. 6 illustrates an envelope-tracking power amplifier including a plurality of switches in a stacked configuration, in accordance with an exemplary embodiment of the present invention.

FIG. 7 is another plot illustrating various signals associated with the envelope-tracking power amplifier depicted in FIG. 6.

FIG. 8 illustrates another device including a plurality of switches in a stacked configuration, according to an exemplary embodiment of the present invention.

FIG. 9 is a plot illustrating various signal associated with the device illustrated in FIG. 8.

FIG. 10 is another plot illustrating various signal associated with the device depicted in FIG. 8.

FIG. 11 illustrates another envelope-tracking power amplifier including a plurality of switches in a stacked configuration, in accordance with an exemplary embodiment of the present invention.

FIG. 12 illustrates a bias circuit coupled to a power amplifier, according to an exemplary embodiment of the present invention.

FIG. 13 is yet another plot illustrating various gains for a power amplifier according to various bias voltages.

FIG. 14 is a flowchart illustrating another method, according to an exemplary embodiment of the present invention.

FIG. 15 is a flowchart illustrating another method, according to an exemplary embodiment of the present invention.

FIG. 16 illustrates a device including one or more power amplifiers, in accordance with an exemplary embodiment of the present invention.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

FIG. 1 illustrates a device 100 including an envelope-tracking power amplifier (ETPA) 102 coupled to an envelope amplifier 104. Envelope-tracking power amplifier 102, which may include a plurality of switchable elements (e.g., transistors) in a stacked configuration, is configured to receive an RF input signal (i.e., a modulated RF input signal) 106 and a supply voltage VDD from envelope amplifier 104. Further, device 100 is configured to convey an output signal (i.e., a modulated RF output signal) 108. Generally, to maximize the efficiency of power amplifier 102, supply voltage VDD can track the envelope of RF input signal 106. With reference to a plot 150 illustrated in FIG. 2, a signal 152 represents a supply voltage for a conventional power amplifier and signal 154 represents a supply voltage (e.g., supply voltage VDD) for an envelope-tracking power amplifier, such as envelope-tracking power amplifier 102. As illustrated in plot 150, the supply voltage for the envelope-tracking power amplifier changes with a power level of an RF input signal (i.e., “RF input power”), while the supply voltage for the conventional power amplifier remains constant as the power level of the RF input signal changes.

As will be appreciated by a person having ordinary skill in the art, adjusting supply voltage VDD of envelope-tracking power amplifier 102 may cause undesirable performance results. More specifically, a gain of envelope-tracking power amplifier 102 may drop as supply voltage VDD decreases, which may cause AM-AM distortion, and may lead to degraded linearity performance of envelope-tracking power amplifier 102.

FIG. 3 is a plot 200 illustrating gain variation of a device including an envelope-tracking power amplifier (e.g., device 100). As depicted in plot 200, the gain variation across a supply voltage, as illustrated by arrow 202, is relatively large, which, as noted above, may cause AM-AM distortion, and may lead to degraded linearity performance.

Exemplary embodiments, as described herein, are directed to devices, systems, and methods related to an adaptive envelope-tracking power amplifier. According to one exemplary embodiment, a device may include a first transistor of a plurality of transistors in a stacked configuration configured to receive a supply voltage, which varies an envelope of an RF input signal. The device may further include a second transistor of the plurality in the stacked configuration coupled to a reference voltage and configured to receive a dynamic bias voltage having a value that varies inversely proportional to the supply voltage. According to another exemplary embodiment, a power amplifier may include a plurality of cascode-configured switching elements coupled between a reference voltage and a supply voltage, wherein the supply voltage varies with an envelope of a radio-frequency (RF) signal that is received at a switching element of the plurality of cascode-configured switching elements. The power amplifier may also include a bias circuit configured to provide a dynamic bias voltage to the switching element, wherein the dynamic bias voltage varies inversely proportional to the supply voltage.

According to another exemplary embodiment, the present invention includes methods for operating an envelope-tracking power amplifier. Various embodiments of such a method may include receiving a supply voltage at a first transistor of a plurality of transistors in a stacked configuration and receiving a radio-frequency input signal at a second transistor of the plurality of transistors. The method may also include receiving a bias voltage varying inversely proportional to the supply voltage at the second transistor. In accordance with yet another exemplary embodiment of the present invention, a method may include conveying a supply voltage to a first switching element of a plurality of switching elements in a stacked configuration. In addition, the method may include conveying a bias voltage that varies inversely proportional to the supply voltage to a second switching element of the plurality of switching elements in the stacked configuration.

Other aspects, as well as features and advantages of various aspects, of the present invention will become apparent to those of skill in the art though consideration of the ensuing description, the accompanying drawings and the appended claims.

FIG. 4A depicts a device 250 including a plurality of switching elements, according to an exemplary embodiment of the present invention. More specifically, according to one exemplary embodiment, device 250 in includes a plurality of transistors M1-MN in a stacked configuration. As illustrated in FIG. 4A, transistor MN (i.e., the topmost transistor in the stack) has a drain coupled to supply voltage VDD and a source coupled to a drain of another transistor of the stack. Further, transistor M1 (i.e., the bottommost transistor in the stack) includes a source coupled to a reference voltage (e.g., a ground voltage GRND) and a drain coupled to a source of another transistor of the stack. A gate of transistor MN is configured to receive a bias voltage VGn via a resistor RN and a gate of transistor M1 is configured to receive a bias voltage VG1 via a resistor R1.

According to one exemplary embodiment of the present invention, bias voltage VG1 may be adjusted in response to a change in supply voltage VDD to compensate for gain variation of device 250. More specifically, bias voltage VG1 may comprise a DC bias voltage that may be tuned inversely proportional to supply voltage VDD. Accordingly, when supply voltage VDD is decreased, bias voltage VG1 may be increased to compensate for a gain drop caused by decreasing supply voltage VDD. Further, when supply voltage VDD is increased, bias voltage VG1 may be decreased. It is noted bias voltage VG1 can be adjusted to shape the gain of device 250 to minimize AM-AM variations of device 250. It is further noted that, in addition to receiving a dynamic bias voltage (i.e., bias voltage VG1), the gate of transistor M1 may also be configured to receive an RF input signal (e.g., a modulated RF input signal). Further, one or more of the other bias voltages of device 250 (i.e., bias voltages VG2-VGN) may be proportional to supply voltage VDD, or fixed.

FIG. 4B is another illustration of device 250. As illustrated in FIG. 4B, a bias circuit 252 may be configured to receive a voltage VG1top and convey dynamic bias voltage VG1 at the gate of transistor M1. Further, an RF input signal may be conveyed to the gate of transistor M1. Accordingly, the gate of transistor M1 may receive an RF input signal and bias voltage VG1 from bias circuit 252 that varies inversely proportional to supply voltage VDD.

FIG. 5 is a plot 300 illustrating supply voltage levels relative to a voltages at a gate of a transistor in a stacked configuration. More specifically, plot 300 includes a signal 302 that represents supply voltage VDD (e.g., supply voltage VDD of device 250; see FIGS. 4A and 4B). Further, signal 304 represents a dynamic bias voltage (e.g., bias voltage VG1; see FIGS. 4A and 4B) relative to the supply voltage, which is represented by signal 302. As illustrated in plot 300, signal 304 (e.g., bias voltage VG1) is inversely proportional to signal 302 (e.g., supply voltage VDD).

For example only, supply voltage VDD may range from 1.5 volts to 3.5 volts and bias voltage VG1 may respectively vary from 0.38 volts to 0.26 volts. More specifically, if supply voltage is substantially equal to 1.5 volts, bias voltage VG1 may be substantially equal to 0.38 volts. Further, if supply voltage is substantially equal to 2.5 volts, bias voltage VG1 may be substantially equal to 0.32 volts. In addition, if supply voltage is substantially equal to 3.5 volts, bias voltage VG1 may be substantially equal to 0.26 volts.

FIG. 6 illustrates an envelope-tracking power amplifier 310, according to an exemplary embodiment of the present invention. Envelope-tracking power amplifier 310 includes device 250 (see FIGS. 4A & 4B) and is configured to receive supply voltage VDD and am RF input signal 312, which may comprise a modulate RF input signal. Further, envelope-tracking power amplifier 310 is configured to output an RF output 314, which may comprise a modulated RF output signal. As noted above, in addition to receiving RF input signal 312, a gate of transistor M1 may receive bias voltage VG1 that varies inversely proportional to supply voltage VDD. It is noted that power amplifier 310 may comprise any type of suitable power amplifier, such as a class AB power amplifier, a class G power amplifier or a class H power amplifier.

FIG. 7 is a plot 350 depicting gain variation of a device (e.g., device 250), including a plurality of transistors in a stacked configuration, wherein a bottommost transistor of the stacked configuration is configured to receive a dynamic bias voltage that varies inversely proportional to a supply voltage received at terminal (e.g., a drain) of a topmost transistor in the stack. In comparison to plot 200 illustrated in FIG. 3, the gain variation shown in plot 350 is substantially reduced. More specifically, the gain curves 352 illustrated in plot 350 remain relatively constant across varying supply voltages for outputs (Pout) from around −13 dBm to 10 dBm. In contrast, the gain curves illustrated in plot 200 vary significantly (0 dBm to 15 dBm) for differing supply voltages. Accordingly, AM-AM distortion of device 250 is significantly improved with respect to device 100 shown in FIG. 1.

FIG. 8 illustrates another device 400, in accordance with an exemplary embodiment of the present invention. Device 400 includes a plurality of transistors M1-MN in a stacked configuration, similar to device 250 of FIGS. 4A and 4B. The gate of transistor MN is configured to receive bias voltage VGn via resistor RN. According to one exemplary embodiment a value of bias voltage VGn may be proportional to supply voltage VDD. According to another exemplary embodiment, a value of bias voltage VGn may be fixed.

Further, a gate of transistor M1 is configured to receive an RF input. Moreover, the gate of transistor M1 is configured to receive a bias voltage via an adaptive bias 402, which is configured to receive a voltage VG1top and convey a bias voltage VG1′ to the gate of transistor M1. Voltage VG1top may be a fixed voltage or a dynamic voltage, which is inversely proportional to supply voltage VDD. In comparison to device 250 (see FIGS. 4A and 4B), which includes transistor MN that receives bias voltage VG1 that is independent of a power level of the RF input signal (i.e., bias voltage VG1 is not affected by an increase in a power level of the RF input signal), adaptive bias 402, may modify bias voltage VG1′, which is conveyed to the gate of transistor M1, in response to a change in a power level of the RF input signal. More specifically, as an example, if the power level of the RF input signal increases, bias voltage VG1′ may also be increased. As a more specific example, if voltage VG1top and supply voltage VDD are fixed, and a modulated RF input signal conveyed to the gate of transistor M1 increases, adaptive bias 402 may increase gate voltage VG1′.

FIG. 9 is a plot 450 illustrating various voltages of device 400 relative to a power level of an RF input signal. As illustrated in plot 450, if supply voltage VDD, which is represented by signal 452, and voltage VG1top, which is represented by signal 454, are each fixed, bias voltage VG1′, which is represented by signal 456, increases for an increasing power level of the RF input signal.

FIG. 10 is another plot 500 illustrating various voltages of device 400 relative to the power level of the RF input signal. Signal 502 represent supply voltage VDD, which increases with an increase in the power level of the RF input signal. Further, a signal 504 represents bias voltage VG1′ in an embodiment wherein voltage VG1top is a dynamic voltage that changes inversely proportion to supply voltage VDD. Further, signal 506 represents bias voltage VG1′ in an embodiment wherein voltage VG1top is a fixed voltage.

FIG. 11 illustrates an envelope-tracking power amplifier 550, according to an exemplary embodiment of the present invention. Envelope-tracking power amplifier 550 includes device 400 (see FIG. 8) and is configured to receive supply voltage VDD and a RF input signal 552, which may comprise a modulate RF input signal. Further, envelope-tracking power amplifier 550 is configured to output an RF output signal 554, which may comprise a modulated RF output signal. As noted above, in addition to receiving RF input signal 312, a gate of transistor M1 may receive bias voltage VG1′ that varies inversely proportional to supply voltage VDD. It is noted that power amplifier 550 may comprise any type of suitable power amplifier, such as a class AB power amplifier, a class G power amplifier or a class H power amplifier.

FIG. 12 illustrates a device 560 including a bias circuit 562 coupled to a power amplifier 570, according to an exemplary embodiment of the present invention. Although power amplifier 570 is different from power amplifiers 310 and 550, device 560 may include either power amplifier 310 or power amplifier 550, rather than power amplifier 570. As illustrated in FIG. 12, bias circuitry 562 includes an amplifier replica 562 a linearization circuit replica 564 and a linearization circuit 566. Replica linearization circuit, which includes transistors Fy2 and Fy1, and amplifier replica, which includes transistors Mx1-Mxn, may be configured to ensure process/voltage/temperature (PVT) tracking. Further, linearization circuit 566 includes a source follower (F2) and a diode-connected transistor (F1).

Moreover, device 560 may include a reconfigurable connection for supply voltage VDD_Ladder, as illustrated by reference numeral 572. Connection of supply voltage VDD_Ladder is reconfigurable to change circuit behavior as desired. When supply voltage VDD_Ladder is connected to VDD_Bias, gate bias of transistor M1 is independent of PA voltage VDD_PA. When supply voltage VDD_Ladder is connected to VDD_PA, gate bias of transistor M1 is inversely proportional to PA voltage VDD_PA, thus improving gain at low power. This may be especially helpful in envelope tracking applications. It is noted that bias circuitry 562 is provided as an example of a bias circuit configured to generate a bias voltage that varies inversely proportional to a supply voltage (e.g., supply voltage VDD), and the invention is not so limited. Rather, the present invention may include any suitable bias circuitry configured to generate a bias voltage that varies inversely proportional to a supply voltage.

As will be understood by a person having ordinary skill, beyond reducing gain variation, controlling the gain shape may allow for AM-AM distortion to be minimized and improved efficiency. FIG. 13 is a plot 600 illustrating variations in gain of an amplifier. As will be understood by a person having ordinary skill in the art, a gain shape of an amplifier (e.g., amplifier 250) may be controlled by the slope of bias voltage VG1 over supply voltage VDD. More specifically, signals 604, 606, and 608 illustrate various gains of an amplifier (e.g., amplifier 250) according to various values of a bias voltage (e.g., bias voltage VG1 of FIG. 4B). As will be appreciated by a person having ordinary skill in the art, controlling a shape of a gain of an amplifier may improve back-off efficiency and minimize AM-AM variation.

FIG. 14 is a flowchart illustrating a method 650, in accordance with one or more exemplary embodiments. Method 650 may include receiving a supply voltage at a first transistor of a plurality of transistors in a stacked configuration (depicted by numeral 652). Method 650 may also include receiving a radio-frequency (RF) input signal at a second transistor of the plurality of transistors (depicted by numeral 654). Further, method 650 may include receiving a bias voltage varying inversely proportional to the supply voltage at the second transistor (depicted by numeral 656).

FIG. 15 is a flowchart illustrating another method 700, in accordance with one or more exemplary embodiments. Method 700 may include conveying a supply voltage to a first switching element of a plurality of switching elements in a stacked configuration (depicted by numeral 702). Method 700 may also include conveying a voltage varying inversely proportional to the supply voltage to a second switching element of the plurality of switching elements in a stacked configuration (depicted by numeral 704).

FIG. 16 is a block diagram of a device 800, according to an exemplary embodiment of the present invention. According to one example, device 800 may include a wireless communication device. In this example, wireless communication device 800 includes one or more modules, such as a digital module 802 and an RF module 804. Digital module 804 may comprise memory and one or more processors. RF module 806, which may comprise a radio-frequency integrated circuit (RFIC), may include a transceiver 806 including a transmitter 808 and a receiver 810 and may be configured for bi-directional wireless communication via an antenna 812. In general, wireless communication device 800 may include any number of transmitters and any number of receivers for any number of communication systems, any number of frequency bands, and any number of antennas. Further, one or more transmitters 808 within RF module 804 may include one or more power amplifiers, such as power amplifier 310 (see FIG. 6) and power amplifier 550 (see FIG. 11).

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A device, comprising:
a first transistor of a plurality of transistors in a stacked configuration configured to receive a supply voltage varying with an envelope of a radio-frequency (RF) input signal; and
a second transistor of the plurality in the stacked configuration coupled to a reference voltage and configured to receive a dynamic bias voltage varying inversely proportional to the supply voltage.

2. The device of claim 1, the first transistor configured to receive one of a fixed bias voltage and a dynamic bias voltage varying proportional to the supply voltage.

3. The device of claim 1, the first transistor having a drain configured to receive the supply voltage and the second transistor having a source coupled to a ground voltage.

4. The device of claim 1, a gate of the second transistor configured to receive the dynamic bias voltage and the RF input signal.

5. The device of claim 1, wherein the dynamic bias voltage is dependent on a power level of the RF input signal.

6. The device of claim 1, further comprising a bias circuit configured to generated the dynamic bias voltage varying inversely proportional to the supply voltage.

7. A device, comprising:
a plurality of cascode-configured switching elements coupled between a reference voltage and a supply voltage, the supply voltage varying with an envelope of a radio-frequency (RF) signal received at a switching element of the plurality of cascode-configured switching elements; and
a bias circuit configured to provide a dynamic bias voltage to the switching element, wherein the dynamic bias voltage varies inversely proportional to the supply voltage.

8. The device of claim 7, the switching element further configured to receive the RF input signal at a gate.

9. The device of claim 7, wherein at least one other switching element of the plurality of cascode-configured switching elements is configured to receive one of a fixed bias voltage and a dynamic bias voltage varying proportional to the supply voltage.

10. The device of claim 7, the switching element having a source configured to receive the reference voltage.

11. The device of claim 7, wherein another switching element of the plurality of cascode-configured switching elements has a drain coupled to the supply voltage.

12. The device of claim 7, wherein the dynamic bias voltage increases with an increase in a power level of the RF signal.

13. The device of claim 7, further configured to operate as one of a class AB amplifier, a class G amplifier, and a class H amplifier.

14. A method, comprising:
receiving a supply voltage at a first transistor of a plurality of transistors in a stacked configuration;
receiving a radio-frequency (RF) input signal at a second transistor of the plurality of transistors; and
receiving a bias voltage varying inversely proportional to the supply voltage at the second transistor.

15. The method of claim 14, further comprising receiving one of a fixed bias voltage and a dynamic bias voltage varying proportional to the supply voltage at the first transistor.

16. The method of claim 14, wherein receiving a supply voltage comprises receiving a supply voltage varying with an envelope of the RF input signal.

17. The method of claim 14, wherein receiving a bias voltage varying inversely proportional to the supply voltage at the second transistor comprises receiving the bias voltage at the second transistor having a source coupled to a ground voltage.

18. The method of claim 14, wherein receiving a supply voltage at the first transistor comprises receiving the supply voltage at a drain of the first transistor.

19. The method of claim 14, further comprising increasing the bias voltage if a power level of the RF input signal increases.

20. A method, comprising:
conveying a supply voltage to a first switching element of a plurality of switching elements in a stacked configuration; and
conveying a bias voltage varying inversely proportional to the supply voltage to a second switching element of the plurality of switching elements in a stacked configuration.

21. The method of claim 20, further comprising:
conveying a radio-frequency (RF) input signal to the second switching element; and
conveying an output RF signal from a drain of the first switching element.

22. A device, comprising:
means for receiving a supply voltage at a first transistor of a plurality of transistors in a stacked configuration;
means for receiving a radio-frequency (RF) input signal at a second transistor of the plurality of transistors; and
means for biasing the second transistor with a bias voltage varying inversely proportional to the supply voltage.

23. The device of claim 22, further comprising means for biasing the first transistor with one of a fixed bias voltage and a dynamic bias voltage varying proportional to the supply voltage.

24. The device of claim 22, wherein the means for receiving a supply voltage comprises means for receiving the supply voltage varying with an envelope of the RF input signal.

25. A device, comprising:
means for conveying a supply voltage to a first switching element of a plurality of switching elements in a stacked configuration; and
means for conveying a bias voltage varying inversely proportional to the supply voltage to a second switching element of the plurality of switching elements in a stacked configuration.

26. The device of claim 25, further comprising means for conveying a radio-frequency (RF) input signal to the second switching element.
